(19) United States
(12) Patent Application Publication
(10) Pub. No.: US 2011/0220199 A1
(43) Pub. Date: Sep. 15, 2011

(54) Inkjet Ink

(75) Inventors: Martyn John Robinson, Cambridge (GB); Philip Gareth Bentley, Cambridge (GB)

(73) Assignee: CONDUCTIVE INKJET TECHNOLOGY LIMITED, Ossett, Yorkshire (GB)

(21) Appl. No.: 13/127,416

(22) PCT Filed: Oct. 30, 2009
(86) PCT No.: PCT/GB2009/051468

§ 371 Date: May 18, 2011

(30) Foreign Application Priority Data
Nov. 4, 2008 (GB) 0820126.1

(51) Int. Cl. H01L 31/0216; C09D 11/02; H01L 21/22; H01L 21/306

(52) U.S. Cl. 136/256; 106/31.13; 438/558; 438/745; 257/E31.119; 257/E21.135; 257/E21.219

(57) ABSTRACT

An inkjet ink comprises phosphoric acid; one or more solvents for the phosphoric acid, preferably ethyl lactate and water; and one or more aprotic organic sulfoxides, preferably dimethyl sulfoxide (DMSO) or dimethyl sulfone (SMSO₂). The inks do not leave a carbon residue on heating and so are suited to use in etching and/or doping silicon wafers, e.g. in the production of crystalline silicon solar cells.

### FIELD OF THE INVENTION

This invention concerns an inkjet ink and the use thereof in processing silicon materials, for doping and/or etching, with particular, but not exclusive, application in the production of crystalline silicon solar cells.

### BACKGROUND TO THE INVENTION

A typical crystalline silicon solar cell comprises a silicon wafer, with a p-n solar cell usually being made using a p-type silicon substrate doped to produce a layer of n-type material on the front face of the wafer. A capping layer, e.g. of silicon nitride, is provided on the front face of the wafer, over the n-type material, to passivate the silicon surface and provide an anti-reflective coating. Electrical contact to the rear face of the wafer may be provided by coating the entire rear face, over the p-type material, with a suitable material, such as aluminium. Electrical contact to the front face of the wafer is commonly made by an arrangement of finger electrodes. These are conveniently produced by etching trenches through the silicon nitride passivation layer and filling the trenches with suitable contact material. It is beneficial to efficient functioning of the solar cell to concentrate the n-type doping under the electrode fingers, with highly doped n++ regions selectively positioned beneath the electrodes.

It is known to etch trenches in the passivation layer using phosphoric acid, which is a selective etchant for silicon nitride but not silicon, so that etching stops at the silicon surface. In addition, phosphorus is an n-type dopant for silicon, and annealing at high temperature, e.g. 800° C., allows phosphorus atoms from applied phosphoric acid to diffuse into silicon, forming highly doped n++ regions beneath the trenches.

US 2004/0242019 discloses use of a phosphoric acid paste in production of silicon solar cells, for etching and doping a passivated silicon substrate. The phosphoric acid paste is applied to a passivated silicon substrate and heated to a temperature in the range 250-350° C. for 30-120 seconds for etching, and then subsequently heated to a temperature in the range 800-1050° C. for 20-40 minutes for n++ doping of the silicon. Screen printing is a contact printing process and can only be used with a silicon substrate that is mechanically robust enough to withstand the process, and so is unsuitable for treatment of thin wafers, e.g. having a thickness of 200 micron or less. A further drawback is that screens used in screen printing have a limited lifetime and can stretch in use, affecting placement, possibly resulting in problems of alignment. The document makes passing reference to the possibility of applying the phosphoric acid etching medium by inkjet printing, but gives no consideration to the formulation of media suitable for inkjet printing. The examples use screen printing to apply a phosphoric acid paste that is totally unsuited to inkjet printing, being too viscous.

As is well known in the art, it is not a trivial matter to formulate an inkjet ink, as the inks are subject to many constraints. In particular, the ink must have a viscosity and surface tension within narrow ranges appropriate for the print head with which the ink is to be used. The surface tension must also be appropriate to enable good control of the ink on the intended substrate. The ink must also be chemically compatible with the intended print head, which presents particular problems with acidic inks. The volatility of the ink must also be constrained within tight limits, as rapid evaporation of ink components in use may result in the ink drying within the print head and blocking the printing nozzles. In particular, it is necessary for an ink to have a reasonable “dwell time”, that is the length of time that the ink can be left in an uncapped print head while retaining jettability. The ink must also be stable in storage. In addition, the ink must have appropriate properties and behaviour in any intended processing steps such as heating for annealing and/or doping as mentioned above.

### SUMMARY OF THE INVENTION

In one aspect the present invention provides an inkjet ink, comprising at least 10% by weight of phosphoric acid; one or more solvents for the phosphoric acid; and one or more aprotic organic sulfoxides.

The phosphoric acid is typically in the form of an aqueous solution, e.g. 85% phosphoric acid (ie an aqueous solution containing 85% by weight phosphoric acid). It is useful for the ink to contain as much phosphoric acid as possible for efficient functioning, as will be discussed below, subject to satisfying constraints on formulating an inkjet ink as noted above. The ink preferably includes at least 15% by weight, more preferably at least 25% by weight, of 85% phosphoric acid. Good results have been obtained with inks containing 25% by weight of 85% phosphoric acid, particularly in terms of control of line width after etching.

The aprotic organic sulfoxide or sulfoxides of the ink are hydrophilic, high boiling point materials which reduce solvent evaporation from the ink and so act as humectants, preventing the ink drying within the print head and blocking the printing nozzles, and so improving dwell times, and also increasing ink viscosity and improving jetting performance. The use of one or more aprotic organic sulfoxides as humectants enables production of phosphoric acid-containing inks suitable for inkjet printing. The sulfoxides are aprotic, i.e. neither donating nor accepting protons, and so do not react with phosphoric acid, e.g. to produce salts. Furthermore, most common humectants will carbonise on heating to the high temperatures required to allow etching and/or doping of silicon wafers, and so would leave a carbon-containing residue on the wafer surface and contaminate processing equipment in an unacceptable manner. In contrast, aprotic organic sulfoxides do not leave a carbon residue on heating and so are suited to use in etching and/or doping silicon wafers. Suitable aprotic organic sulfoxides include sulfolane (boiling point 285° C.) (although this may produce odiferous sulphur compounds in use and so is less preferred), dimethyl sulfoxide (DMSO) (boiling point 189° C.) and dimethyl sulfone (DMSO₂) (boiling point 237° C.). The currently preferred aprotic organic sulfoxide humectant is DMSO₂. A mixture of materials may be used. Aprotic organic sulfoxide is conveniently present in an amount in the range 10-30% by weight, preferably 15-25% by weight, based on the total weight of the ink. Good results have been obtained with inks including 20% by weight DMSO₂.

The ink typically includes water as a solvent for the phosphoric acid. However, a solution of phosphoric acid in water is not suitable for inkjet printing due to its high surface tension and low viscosity, and the ink therefore typically includes water and one or more non-aqueous co-solvents. Many suitable potential co-solvents are well known in the art. The co-solvent should be selected for compatibility with the other ink ingredients, and in particular should be non-reactive with the phosphoric acid. The co-solvent should also be compatible with the intended printhead and substrate and intended processing of the ink. One skilled in the art can readily select one or more appropriate co-solvents. Good results have been obtained using ethyl lactate, which reduces the surface tension of the solution of phosphoric acid in water, is miscible with water and aprotic organic sufoxides, and does not react with phosphoric acid. Ethyl lactate is volatile, having a boiling point of 154° C., and evaporates completely from the ink on heating, e.g. during etching. Other suitable co-solvents can be readily identified. A mixture of co-solvents may be used.

The solvent conveniently includes water, e.g. deionized (DI) water (in addition to the water content of the phosphoric acid) typically in an amount in the range 20-30% by weight and non-aqueous co-solvent, e.g. ethyl lactate, typically in an amount in the range 20-30% by weight.

The ink may include optional additives, as is well known in the art, such as surfactant, to improve wetting on the substrate, e.g. in an amount up to 1% by weight. Other possible optional ingredients are well known to those skilled in the art.

Inkjet inks in accordance with the invention may be readily made, eg by mixing the various ingredients.

Inks in accordance with the invention can be stable in storage and have good jetting properties and dwell times. In addition, the inks do not leave a carbon residue on heating and so find application in etching and/or doping silicon materials, such as in the production of crystalline silicon solar cells.

In a further aspect the invention provides a method of doping a silicon material substrate, comprising depositing by inkjet printing an inkjet ink in accordance with the invention on surface regions of the silicon material substrate to be doped; and subsequently heating at least said surface regions to produce n-type doping of the silicon material by phosphorus atoms from the phosphoric acid.

Heat treatment for doping typically involves heating to a temperature in excess of 800° C., for example a temperature in the range 800-1050° C. for 20-40 minutes.

The ink is typically applied patternwise to produce localised doping.

The substrate is conveniently a crystalline silicon wafer, for example in use in a crystalline silicon solar cell.

The method may be used to produce highly doped n++ regions.

Doping a silicon material substrate by the method of the invention may take place prior to coating the substrate with a passivation layer. In this case, it is then necessary to align trenches in the coating for contacts with the doped regions, for optimum functioning. It is therefore preferred to carry out doping after coating, conveniently using phosphoric acid for both the etching and doping processes, as this results in self-alignment of the trenches for contacts with the doped regions.

The invention also includes within its scope a method of etching a surface coating on a silicon material substrate, comprising depositing by inkjet printing an inkjet ink in accordance with the invention on surface regions of the coating to be etched; and subsequently heating at least said surface regions to produce etching.

As noted above, phosphoric acid does not etch silicon, so the ink selectively etches the coating only. This method is therefore useful for producing electrical contacts to coated silicon substrates.

Heating for etching is conveniently at a temperature in excess of 200° C., e.g. in the range 200-400° C. for up to 30 minutes, and is preferably carried out in a water-rich atmosphere.

The silicon material substrate conveniently comprises a crystalline silicon wafer, e.g. for use in a crystalline silicon solar cell.

The coating is commonly silicon oxide or silicon nitride, e.g. in the form of an anti-reflective passivation layer on a crystalline silicon wafer for a crystalline silicon solar cell, but other coatings are possible such as inorganic, glass-like or crystalline materials as disclosed in US 2003/0160026.

The ink is typically applied patternwise for selective etching, e.g. to produce trenches for electrical contacts of a crystalline silicon solar cell.

The two methods may conveniently be used in conjunction with each other for combined etching and doping, e.g. in production of a crystalline silicon solar cell, as this results in an arrangement in which the trenches for contacts are aligned with doped regions therebelow.

In a preferred aspect the present invention thus provides a method of etching a surface coating on a silicon material substrate and doping the substrate, comprising depositing by inkjet printing an inkjet ink in accordance with the invention on surface regions of the substrate to be etched and doped; subsequently heating at least said surface regions to produce trenches by etching; and subsequently heating at least said regions to produce n-type doping of the silicon material in the vicinity of the trenches.

Electrical contacts are conveniently subsequently formed in known manner in the trenches, aligned with the doped regions.

The method finds particular application in the production of crystalline silicon solar cells, allowing patternwise production of trenches for electrical contacts, with highly doped n++ regions therebelow. Because inkjet printing is a non-contact method, unlike screen printing, the method of the invention may be used with very thin crystalline silicon wafers, e.g. having a thickness of 200 micron or less, for instance having a thickness of 100 microns or less, which are very fragile and unsuited to printing by contact methods such as screen printing.

The invention also covers a silicon material substrate that has been subjected to doping and/or etching by the method of the invention.

The invention also includes within its scope a crystalline silicon solar cell comprising a crystalline silicon wafer with an anti-reflective passivation layer, including trenches in the passivation layer formed by the method of the invention with doped regions therebelow produced by the method of the invention, preferably in a single process with two heating stages, one for etching and then one for doping. The wafer of the solar cell may have the thickness of 200 microns or less, preferably 100 microns or less.

The ink may be applied using any suitable inkjet printer, for example commercially available inkjet printers, including both continuous and drop-on-demand printers, particularly piezoelectric printers.

The invention will be further described, by way of illustration, in the following examples. In the examples, all amounts are % by weight, unless otherwise specified.

### EXAMPLE 1

Various different inks were made up with DMSO as the humectant. The inks were prepared by mixing the ingredients in a sample bottle at room temperature (25° C.), with gentle shaking of the bottle to mix the ingredients. The inks were stable in storage, and were tested for their properties within an inkjet printer used to print the inks onto a substrate of poly-silicon (300 micron thick) with a silicon nitride coating (75 nm thick).

Viscosity was measured using a Brookfield DVI+LV (Brookfield is a Trade Mark) rotational viscometer with UL adapter operating with a rotational speed of 60 rpm at a temperature of 25° C. Briefly, 17.5 ml of the ink composition was transferred to the chamber, to which a suitable spindle was then lowered into the chamber and left until the temperature stabilized. Measurements were taken every 30, 60, 120 and 300 seconds, until a reproducible viscosity reading could be obtained.

Printing was carried out using a Dimatix Materials Printer DMP-2800 (Dimatix is a Trade Mark) with a 10 pl cartridge. A single nozzle was used to print single pixel lines with a 20 micron drop pitch. Good jetting performance is defined as stable jetting, with no loss of jetting with time. Acceptable jetting performance is defined as jetting is achievable, but the nozzle ceases to jet after 2-3 minutes.

Etching was carried out in a furnace at 350° C. A tray of water was placed in the bottom of the furnace prior to testing, and heated to 100° C., to raise the humidity within the furnace. With the water absent, etching was very poor. Samples were placed into the furnace immediately following printing, and left for 20 minutes. They were then rinsed in a 5% solution of potassium hydroxide for 5 minutes at room temperature, and then rinsed thoroughly with DI water.

Good etching was defined as when a visual inspection showed that the silicon nitride was completely etched through to the silicon layer beneath.

Details are given in the table below.

| | | | | |
|---|---|---|---|---|
| 85% | 25 | 30 | 25 | 25 |
| phosphoric | | | | |
| acid | | | | |
| Deionised | 27.5 | 25 | 27.5 | 22.5 |
| water | | | | |
| DMSO | 20 | 20 | 10 | 30 |
| ethyl lactate | 27.5 | 25 | 37.5 | 22.5 |
| Viscosity, | 8.76 | 12.1 | 7.63 | 11.1 |
| cPs (25° C.) | | | | |
| Jetting | Good- | Acceptable. | Acceptable | Good. Easy |
| | primes | Poorer than | | to prime. |
| | well. | sample with | | Stable jetting. |
| | Stable | 25% | | |
| | jetting | phosphoric | | |
| | | acid | | |
| Etching | Good- | Good-fully | Good-fully | Good-fully |
| | fully etches | etches | etches | etches |
| Line width | 30-40 | 30-40 before | 30-40 before | 50-60 before |
| (μm) | before | etching. 50- | etching. 50- | etching. 140 |
| | etching. | 60 after | 60 after | after etching. |
| | 50-60 after | etching | etching | |
| | etching | | | |

Formulations containing 25% by weight of 85% phosphoric acid were found to give the best results. Increasing the amount of phosphoric acid affected the jetting performance. Reducing the amount of DMSO from 20% to 10% also affected the jetting performance. Increasing the amount of DMSO to 30% gave stable jetting, but caused the width of the resulting lines to increase. With all of the inks, no carbon residue was formed during etching.

### EXAMPLE 2

Various further inks were made up and tested as described in Example 1, using dimethylsulfone (DMSO₂) as the humectant. Because DMSO₂ is a solid at room temperature, the ink ingredients were magnetically stirred for two hours after addition of the ingredients to the sample bottle. These inks were stable in storage.

Details are given in the table below.

| | | |
|---|---|---|
| 85% phosphoric | 25 | 35 |
| acid | | |
| Deionised water | 27.5 | 22.5 |
| DMSO₂ | 20 | 20 |
| Ethyl lactate | 27.5 | 22.5 |
| Viscosity, cPs (25°) | 6.94 | 9.25 |
| Jetting | Good-primes | Jetting acceptable |
| | well, stable jetting | |
| Etching | Good-fully etches | Good-fully etches |
| Line width (μm) | 30-40 before | 30-40 before |
| | etching. 50-60 | etching. 110 after |
| | after etching | etching |

With all of the inks in Examples 1 and 2, no carbon residue was formed during doping and etching.

1. An inkjet ink, comprising at least 10% by weight of phosphoric acid; one or more solvents for the phosphoric acid; and one or more aprotic organic sulfoxides in an amount in the range 10 to 30% by weight.

2. An inkjet ink according to claim 1, wherein the phosphoric acid comprises an aqueous solution of phosphoric acid.

3. An inkjet ink according to claim 2, wherein the phosphoric acid comprises an aqueous solution containing 85% by weight of phosphoric acid.

4. An inkjet ink according to claim 3, wherein the phosphoric acid comprises at least 15%, preferably at least 25%, by weight of 85% phosphoric acid

5. An inkjet ink according to claim 1, wherein the aprotic organic sulfoxide is selected from dimethyl sulfoxide and dimethyl sulfone.

6. An inkjet ink according to claim 1, wherein the solvent comprises water and one or more non-aqueous co-solvents.

7. An inkjet ink according to claim 6, wherein the solvent comprises water in an amount in the range 20-30% by weight and non-aqueous co-solvent in an amount in the range 20-30% by weight.

8. An inkjet ink according to claim 6, wherein the non-aqueous co-solvent comprises ethyl lactate.

9. A method of doping a silicon material substrate, comprising depositing by inkjet printing an inkjet ink according to claim 1 on surface regions of the silicon material substrate to be doped; and subsequently heating at least said surface regions to produce n-type doping of the silicon material.

10. A method according to claim 9, wherein heating is at a temperature in the range 800-1050° C. for 20-40 minutes.

11. A method of etching a surface coating on a silicon material substrate, comprising depositing by inkjet printing an inkjet ink according to claim 1 on surface regions of the coating to be etched; and subsequently heating at least said surface regions to produce etching.

12. A method according to claim 11, wherein heating is at a temperature in the range 200-400° C. for up to 30 minutes.

13. A method according to claim 9, wherein the silicon material substrate comprises a crystalline silicon wafer.

14. A method according to claim 9, wherein the substrate has a surface coating of silicon oxide or silicon nitride.

15. A method according to claim 9, wherein the ink is applied patternwise.

16. A method of etching a surface coating on a silicon material substrate and doping the substrate, comprising depositing by inkjet printing an inkjet ink according to claim 1 on surface regions of the substrate to be etched and doped; subsequently heating at least said surface regions to produce trenches by etching; and subsequently heating at least said regions to produce n-type doping of the silicon material in the vicinity of the trenches.

17. A crystalline silicon solar cell comprising a crystalline silicon wafer with an anti-reflective passivation layer, including trenches in the passivation layer formed by the method of claim 11 with doped regions therebelow produced by the method of claim 9.

18. A crystalline silicon solar cell according to claim 17, wherein the wafer of the solar cell has a thickness of 200 microns or less.
